(19) United States
(12) Patent Application Publication
(10) Pub. No.: US 2026/0040597 A1
(43) Pub. Date: Feb. 5, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Yi Tzu HUANG, Hsinchu (TW); Shu-Uei JANG, Hsinchu (TW); Chih Li CHANG, Hsinchu (TW); Shu-Yuan KU, Hsinchu (TW)

(21) Appl. No.: 18/792,644

(22) Filed: Aug. 2, 2024

(51) Int. Cl. H01L 29/66; H01L 21/3065; H01L 29/06; H01L 29/423; H01L 29/775; H01L 29/786

(52) U.S. Cl. CPC H10D 30/014; H01L 21/3065; H10D 30/43; H10D 30/6735; H10D 30/6757; H10D 62/121; H10D 64/017

(57) ABSTRACT

A method includes forming a fin structure on a substrate, wherein the fin structure includes a first plurality of semiconductor layers made of a first semiconductor material and a second plurality of semiconductor layers made of a second semiconductor material, forming a sacrificial gate stack over the fin structure, removing portions of the fin structure adjacent to the sacrificial gate stack to expose a portion of the substrate, removing edge portions of the second plurality of semiconductor layers in a lateral direction to form recesses, wherein removing the edge portions includes performing a selective dry etching process using a gas etchant that includes ClF₃, forming inner spacers in the recesses, forming a source/drain (S/D) region adjacent to the sacrificial gate stack, removing the sacrificial gate stack and the second plurality of semiconductor layers, and forming a gate structure in place of the sacrificial gate stack and the second plurality of semiconductor layers.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 are perspective views of various stages of manufacturing a semiconductor device structure, in accordance with some embodiments.

FIGS. 6-9 are cross-sectional side views of various stages of manufacturing the semiconductor device structure taken along line A-A of FIG. 5, in accordance with some embodiments.

FIG. 10A is a cross-sectional side view of the semiconductor device structure taken along line A-A of FIG. 5, in accordance with some embodiments.

FIG. 10B is an enlarged view of FIG. 10A, in accordance with some embodiments.

FIG. 10C is a partial top view of FIG. 10A, in accordance with some embodiments

FIG. 11 is a cross-sectional side view of another stage of manufacturing the semiconductor device structure taken along line A-A of FIG. 5, in accordance with some embodiments.

FIGS. 12A and 12B are cross-sectional side views taken along line A-A of FIG. 5 that depict alternative views of the semiconductor device structure at the same stage of the process shown in FIG. 11, in accordance with some embodiments.

FIG. 13A is a cross-sectional side view of the semiconductor device structure taken along line B-B of FIG. 5, at the same stage of the process shown in FIG. 11, in accordance with some embodiments.

FIG. 13B is a cross-sectional side view of the semiconductor device structure taken along line C-C or C′-C′ of FIG. 13A, in accordance with some embodiments.

FIG. 14A is a cross-sectional side view taken along line B-B of FIG. 5 that depicts an alternative view of the semiconductor device structure at the same stage of the process shown in FIG. 13A, in accordance with some embodiments.

FIG. 14B is a cross-sectional side view of the semiconductor device structure taken along line D-D of FIG. 14A, in accordance with some embodiments.

FIGS. 14C and 14D are partial perspective views of the semiconductor device structures shown in the cross-sections of FIGS. 13B and 14B, respectively, in accordance with some embodiments.

FIGS. 14E and 14F are partial top views taken along the X-Y plane of FIG. 5 and corresponding to the semiconductor device structures of FIGS. 13A and 14A, respectively, in accordance with some embodiments.

FIGS. 15-23 are cross-sectional side views of various stages of manufacturing the semiconductor device structure taken along line A-A of FIG. 5, in accordance with some embodiments, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

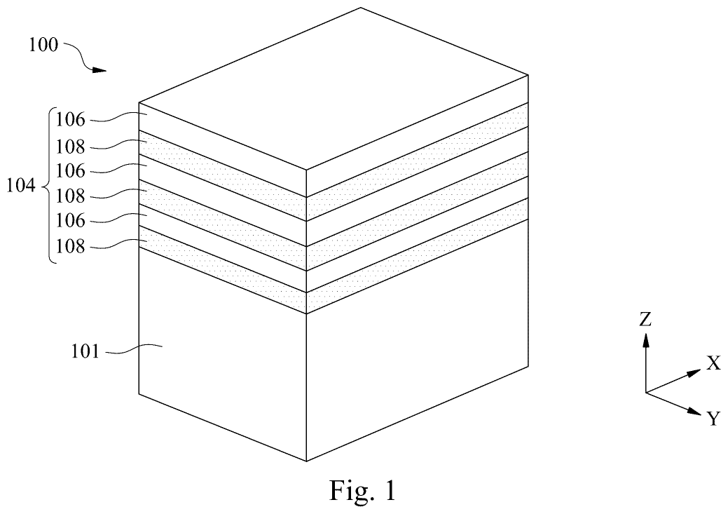

FIGS. 1-23 show exemplary processes for manufacturing a semiconductor device structure 100 according to embodiments of the present disclosure. It is understood that additional operations can be provided before, during, and after processes shown by FIGS. 1-23, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. In some embodiments, the stack of semiconductor layers 104 includes two first semiconductor layers 106. In some embodiments, the stack of semiconductor layers 104 includes three first semiconductor layers 106. In some embodiments, the stack of semiconductor layers 104 includes four first semiconductor layers 106.

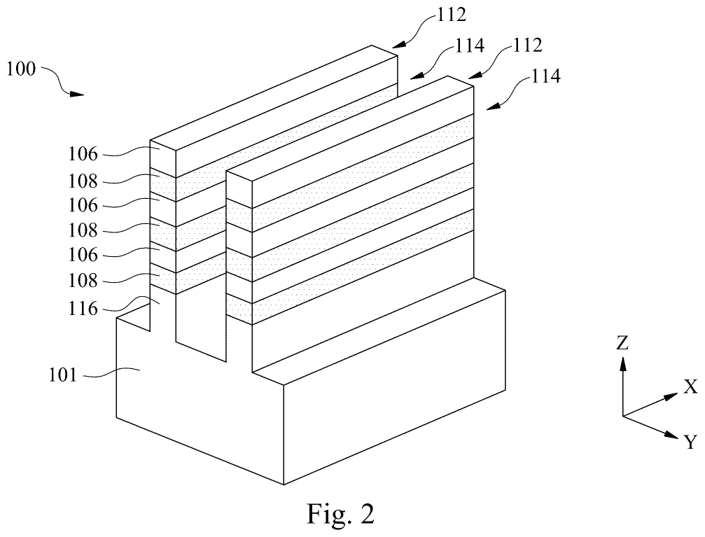

As shown in FIG. 2, fin structures 112 are formed from the stack of semiconductor layers 104 and the substrate 101. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

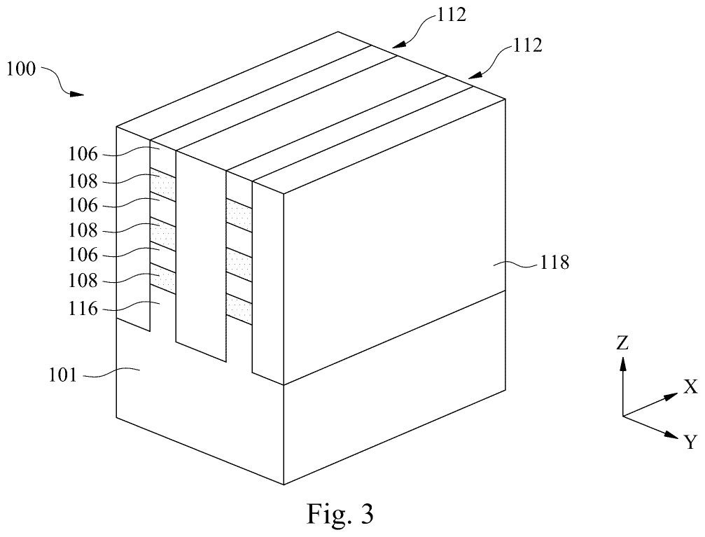

As shown in FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

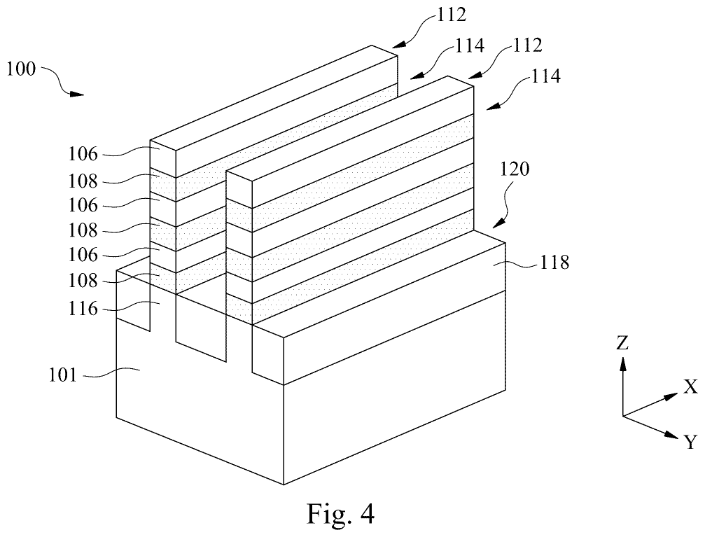

As shown in FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the well portion 116 formed from the substrate 101. In some embodiments, the isolation regions 120 are the shallow trench isolation (STI) regions.

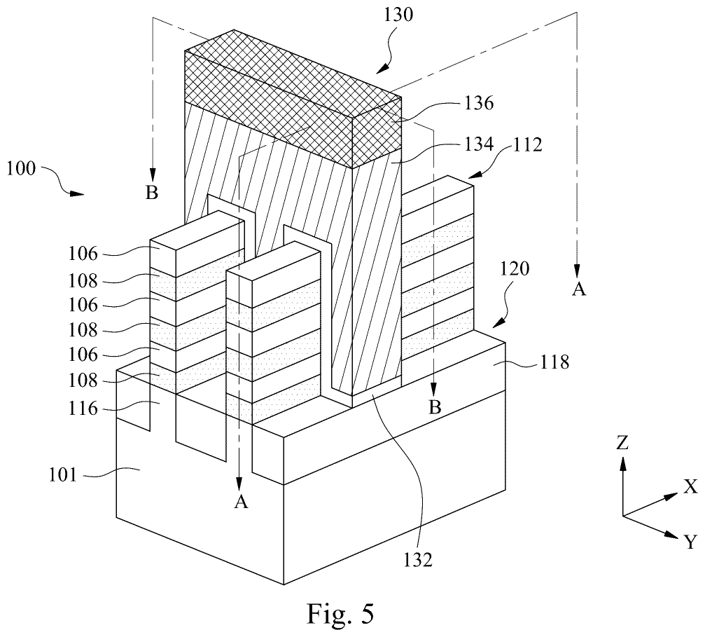

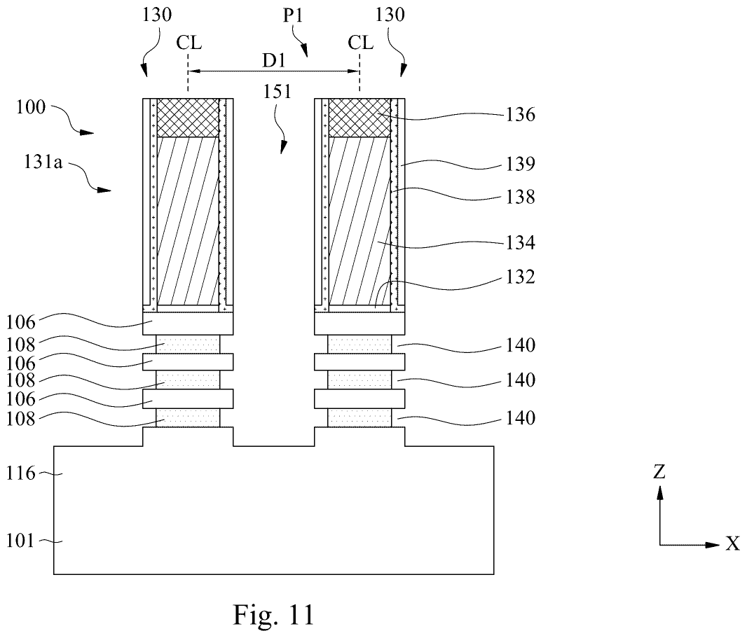

As shown in FIG. 5, one or more sacrificial gate structures 130 (only one is shown), which also may be referred to herein as “sacrificial gate stacks,” are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The semiconductor device structure 100 can include any number of sacrificial gate structures 130. For example, while one sacrificial gate structure 130 is shown, two or more sacrificial gate structures 130 may be arranged along the X direction in some embodiments. In some embodiments, two sacrificial gate structures 130 are shown to be arranged along the X direction, as shown in FIGS. 11 and 15-20.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer over the oxide layer. The portions of the fin structures 112 that are covered by the sacrificial gate electrode layer 134 of the sacrificial gate structure 130 serve as channel regions for the semiconductor device structure 100.

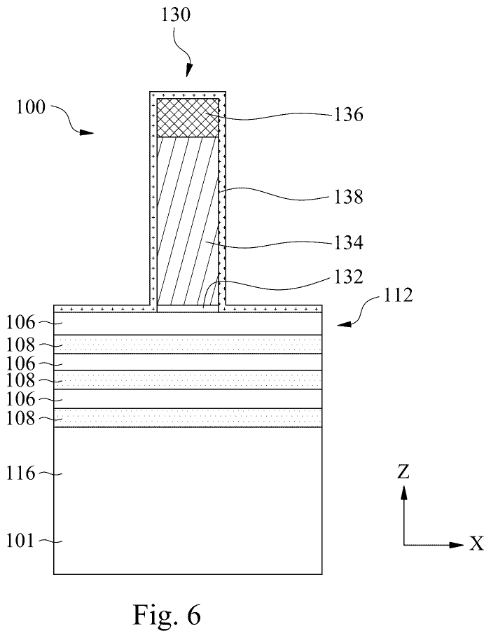

As shown in FIG. 6, a first gate spacer 138 is deposited on the exposed surfaces of the semiconductor device structure 100. For example, the first gate spacer 138 is deposited on the fin structures 112, the isolation regions 120, and the sacrificial gate structure 130. The first gate spacer 138 may be made of a dielectric material such as silicon oxide, silicon nitride, silicon carbide, silicon oxynitride, SiCN, silicon oxycarbide, SiCON, and/or combinations thereof. The first gate spacer 138 may be formed by any suitable process. In some embodiments, the first gate spacer 138 is a conformal layer formed by a conformal process, such as an atomic layer deposition (ALD) process.

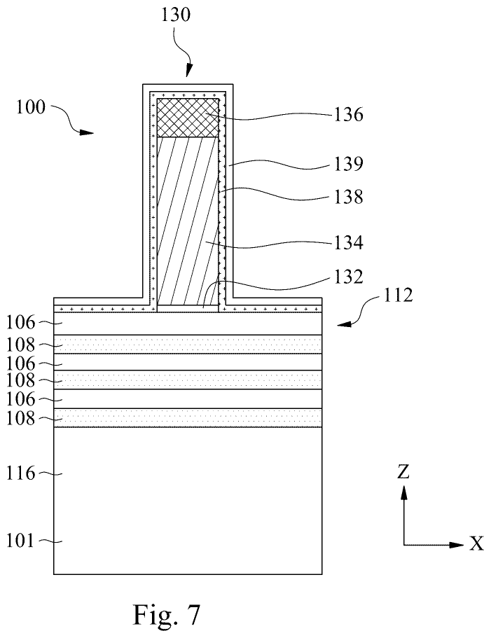

As shown in FIG. 7, a second gate spacer 139 is deposited on the first gate spacer 138. The second gate spacer 139 may include any suitable dielectric material, such as SiOₓ, SiON, SiN, SiCON, or SiCO. The second gate spacer 139 may have a thickness ranging from about 0.5 nm to about 5 nm. The second gate spacer 139 may be formed by any suitable process. In some embodiments, the second gate spacer 139 is deposited by CVD, PECVD, or electron cyclotron resonance CVD (ECR-CVD).

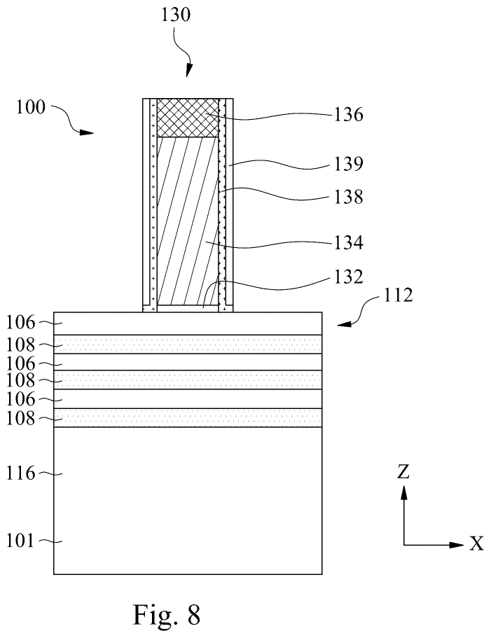

As shown in FIG. 8, horizontal portions of the first and second gate spacers 138, 139 are removed. In some embodiments, the horizontal portions of the first and second gate spacers 138, 139 are removed by an anisotropic etch process. The anisotropic etch process may be a selective etch process that does not substantially affect the mask layer 136, the stack of semiconductor layers 104, and the isolation regions 120.

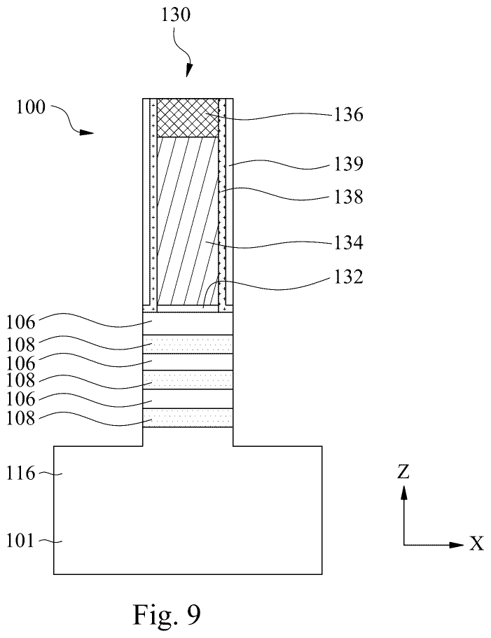

As shown in FIG. 9, the portions of the fin structures 112 not covered by the sacrificial gate structure 130 and the first and second gate spacers 138, 139 are recessed to a level above, at, or below the top surfaces of the isolation regions 120. The recess of the portions of the fin structures 112 can be done by an etch process. The etch process may be a dry etch, such as a RIE, NBE, or the like, or a wet etch, such as using tetramethyalammonium hydroxide (TMAH), ammonium hydroxide (NH₄OH), or any suitable etchant. The well portions 116 are exposed on opposite sides of the sacrificial gate structure 130, as shown in FIG. 9. Even though two gate spacers 138, 139 are shown in the semiconductor device structure 100, less or more dielectric layers may be formed on sidewalls of the sacrificial gate structures 130 as gate spacers depending on the device design and/or manufacturing recipes.

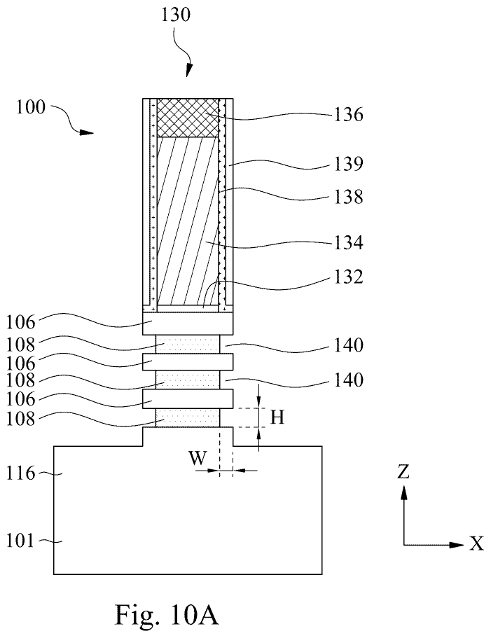

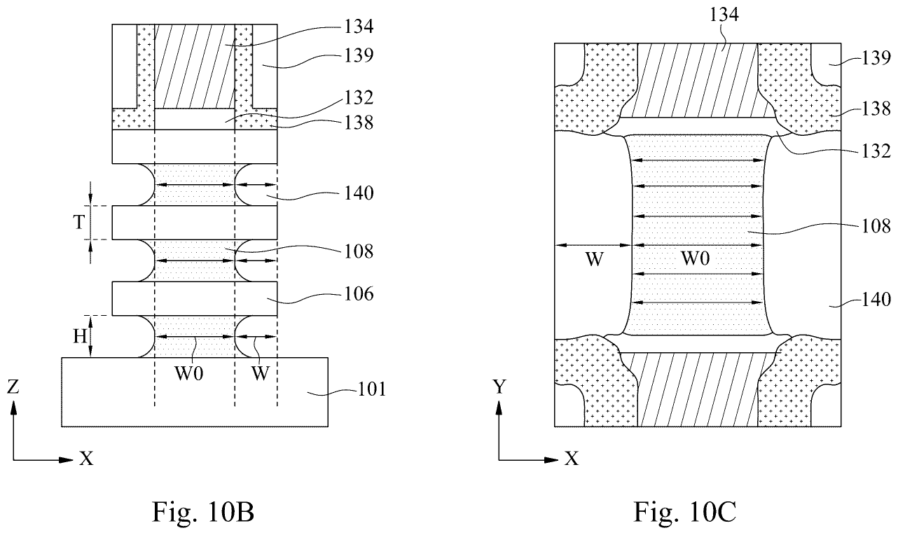

FIG. 10A is a cross-sectional side view of the semiconductor device structure taken along line A-A of FIG. 5, in accordance with some embodiments. FIG. 10B is an enlarged view of FIG. 10A, in accordance with some embodiments. FIG. 10C is a partial top view of FIG. 10A, in accordance with some embodiments. As shown in FIGS. 10A-10C, edge portions of each second semiconductor layer 108 of the stack of semiconductor layers 104 are removed horizontally (laterally) along the X direction. The removal of the edge portions of the second semiconductor layers 108 forms recesses 140. The recesses 140 can be defined in terms of a lateral width W in the X direction and a height H in the Z direction. As shown, the lateral width W can be measured from a location (on the X axis) of a side surface of an adjacent first semiconductor layer 106 (e.g., directly above or below the recess 140) to a location (on the X axis) of a side surface of the second semiconductor layer 108 that is remaining after removal of the respective edge portion. In some embodiments, the lateral width W corresponds to a width of the respective edge portion that is removed. For example, the lateral width W can be measured from a location of a side surface of each second semiconductor layer 108 prior to removal of the respective edge portion (FIG. 9) to a location of a side surface of each second semiconductor layer 108 that is remaining after removal of the respective edge portion (FIG. 10B). In some embodiments, the lateral width W may be within a range between 5 nm and 15 nm. In some embodiments, the lateral width W can differ depending on where each second semiconductor layer 108 is located within the stack of semiconductor layers 104. For example, as shown in FIG. 10B, there are three different positions including a top layer, a middle layer, and a bottom layer, as described in more detail below. In some embodiments, the difference in the lateral width W between different layers can be 1 nm or less, such as 0.5 nm or less, such as 0.3 nm or less.

As shown, the height H can be measured from a bottom surface of a respective first semiconductor layer 106 above each recess 140 to a top surface of a respective first semiconductor layer 106 (or portion of the substrate 101) below each recess 140. In some embodiments, the height H corresponds to a height of the respective edge portion that is removed. For example, the height H can be measured from a location of a top surface to a location of a bottom surface of each second semiconductor layer 108 prior to removal of the respective edge portion (FIG. 9). In some embodiments, the height H may be within a range between 3 nm and 10 nm. In some embodiments, as shown in FIGS. 10B-10C, a width W0 of the remaining portion of the second semiconductor layers 108 (between recesses 140) may be within a range between 5 nm and 20 nm. In some embodiments, the side surfaces of the remaining portion of each second semiconductor layer 108 are curved with respect to the Z direction (FIG. 10B) such that the width W0 at the center (in the Z direction) is less than the width closer to the top or bottom. In some embodiments, a difference in the width between the center and the top or bottom may be within a range between 0 nm and 3 nm. In some embodiments, the side surfaces of the remaining portion of each second semiconductor layer 108 are curved with respect to the Y direction (FIG. 10C) such that the width W0 at the center (in the Y direction) is less than the width closer to the edges of the fin, adjacent the sacrificial gate dielectric layer 132. In some embodiments, a difference in the width (or critical dimension (CD) range) between the center and the edges may be within a range between 0 nm and 3 nm. In some embodiments, a thickness T of the first semiconductor layers 106 may be within a range between 3 nm and 10 nm.

In some embodiments, the edge portions of the second semiconductor layers 108 are removed by performing a selective dry etching process, as described in more detail below. In some embodiments (e.g., when the second semiconductor layers 108 are made of SiGe and the first semiconductor layers 106 are made of silicon), the material of the second semiconductor layers 108 can be selectively etched using a gas etchant that includes ClF₃. In some embodiments, the gas etchant includes, or consists of, a mixture of ClF₃ and F₂. In some embodiments, the gas etchant does not include HF. In some embodiments, a flow rate of ClF₃ is within a range between 50 standard cubic centimeters per minute (SCCM) and 100 SCCM. In some embodiments, a volume fraction of ClF₃ in the gas etchant is within a range between 50% and 100%. In some embodiments, a temperature of the gas etchant and/or a process temperature is within a range between 25° C. and 35° C., such as about 30° C. Using ClF₃ compared to other gases provides certain advantages that are not present in the art, such as improved control of metal gate (MG) critical dimension (CD) profile, reduced loading, improved device performance, and/or improved yield, as described in more detail below.

FIG. 11 depicts an alternative view of the semiconductor device structure 100 at the same stage of the process shown in FIG. 10A. The semiconductor device structure 100 can include any number of sacrificial gate stacks 130, as described above. The process to form the structures that are illustrated in this alternative view optionally include any portion, up to and including all, of the processes described above. To form the structures shown in FIG. 11, the process can include formation of a plurality of sacrificial gate stacks 130 (two are shown) over the fin structures 112. One or more trenches 151 (only one is shown) are formed between different sacrificial gate stacks 130 of the plurality of sacrificial gate stacks 130. The one or more trenches 151 are formed between adjacent stacks of semiconductor layers and between adjacent sacrificial gate stacks 130. In some embodiments, the two sacrificial gate stacks 130 define a first pair 131a of adjacent sacrificial gate stacks 130. In some embodiments, the semiconductor device structure 100 can include any number of pairs of adjacent sacrificial gate stacks 130 (only one is shown). The first pair 131a includes a first distance D1 between the first pair 131a that defines a first pitch P1. In some embodiments, the first distance D1 to define the first pitch P1 is measured between respective centerlines CL of adjacent sacrificial gate stacks 130. In some embodiments, the term “pitch” can be used to indicate that the first distance D1 is applicable to only one pair or more than one pair of adjacent sacrificial gate stacks 130, such as two or more pairs of adjacent sacrificial gate stacks 130. When referring to two or more pairs of adjacent sacrificial gate stacks 130, the term “pitch” may refer to there being equal distances between adjacent sacrificial gate stacks 130 of the same pair and/or equal distances between adjacent sacrificial gate stacks 130 of different pairs. In some embodiments, the term “pitch” can be used to indicate a gate pitch or contacted poly pitch (CPP) that is characteristic of certain semiconductor device structures.

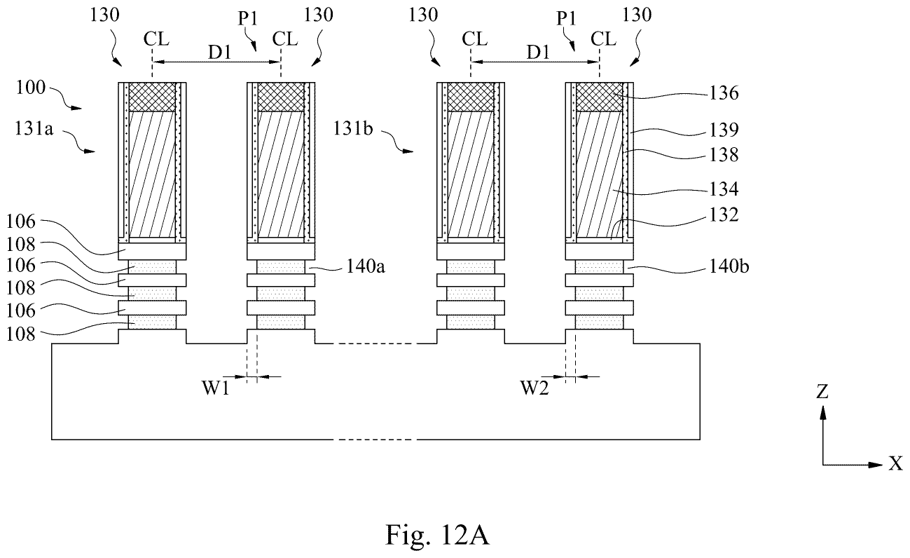

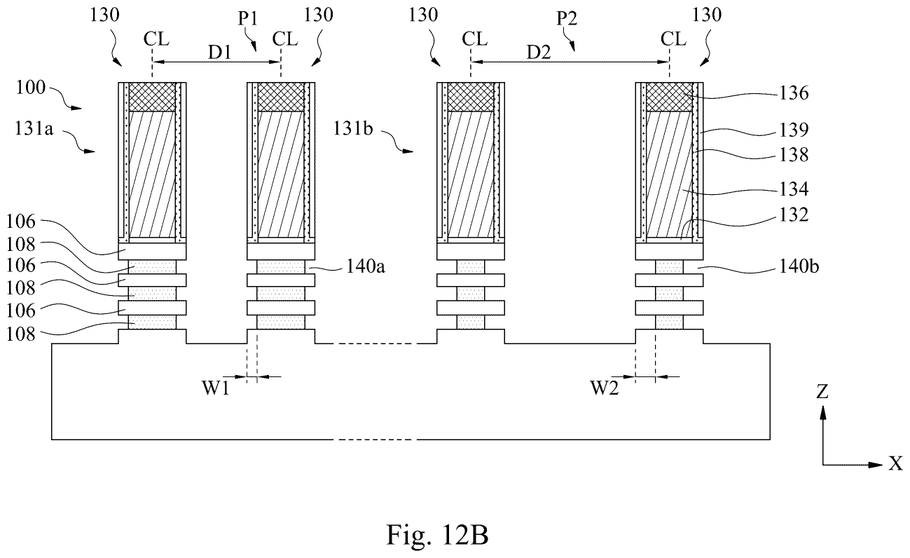

FIGS. 12A and 12B depict alternative views of the semiconductor device structure 100 at the same stage of the process shown in FIG. 11. FIGS. 12A and 12B each include two different pairs of adjacent sacrificial gate stacks 130, which may be located anywhere on the same semiconductor device structure 100. For example, the two different pairs may be located on the same wafer (or the same substrate 101). In some embodiments, the two different pairs may be located directly adjacent to each other in the X direction and/or Y direction. In some embodiments, the two different pairs may be located in different circuit regions, such as logic device regions, memory device regions, and/or input/output device regions, of the same semiconductor device structure 100, wafer, and/or substrate 101. In FIG. 12A, the two different pairs of adjacent sacrificial gate stacks 130 have the same pitch (e.g., the first pitch P1 defined by the first distance D1). In FIG. 12B, the two different pairs of adjacent sacrificial gate stacks 130 have different pitches (e.g., the first pitch P1 and a second pitch P2, defined by a second distance D2, that is different from the first pitch P1). In some embodiments (FIG. 12B), the first pitch P1 is less than the second pitch P2.

With respect to FIGS. 12A and 12B, the recesses 140 that are formed by removing the edge portions of the second plurality of semiconductor layers 108 (as described above) include first recesses 140a associated with the first pair 131a of adjacent sacrificial gate stacks 130 and second recesses 140b associated with the second pair 131b of adjacent sacrificial gate stacks 130. In some embodiments, when the first pitch P1 is equal to the second pitch P2 (FIG. 12A), a first lateral width W1 of the first recesses 140a is equal to a second lateral width W2 of the second recesses 140b. In other words, when the first pitch P1 is the same as the second pitch P2, the loading effect is zero, and the first recesses 140a and the second recesses 140b have equal lateral width. The term “loading effect” refers to process non-uniformity caused by different geometrical features, such as different pattern densities, different pitches, etc. within a substrate, a die, or a device. During an etch process, the loading effect may be caused by different exposed areas or etching areas, making it difficult to control etching uniformity due to the loading effect. Depending on the integration of fin structures and etching strategy, the loading effect is the etching rate for a larger exposed area being either faster or slower than the etching rate for a smaller exposed area. In other words, the loading effect is that the etching rate in large areas is mismatched with the etching rate in small areas. This means that the loading effect may be affected by the pattern density. In some embodiments, when the first pitch P1 is less than the second pitch P2 (FIG. 12B), the first lateral width W1 of the first recesses 140a is less than the second lateral width W2 of the second recesses 140b. In other words, the loading effect is less for the first pitch P1 compared to the second pitch P2, at least because the first pitch P1 is less than the second pitch P2. Using a gas etchant that includes ClF₃, compared to other gases, in the dry etching process to form the recesses 140 can provide significant reductions in loading as described below. For example, with ClF₃, even when the first pitch P1 is less than the second pitch P2, a difference between the first lateral width W1 and the second lateral width W2 is below a threshold that is less than a characteristic threshold for etching differences with other gases. In other words, using a gas etchant that includes HF would result in higher loading, a higher threshold, and greater differences in etching based on gate pitch compared to ClF₃.

In some embodiments, when the first pitch P1 is 80% or less of the second pitch P2, a difference between the first lateral width W1 and the second lateral width W2 is 5% or less of W2. For example, the first lateral width W1 may be 5% or less above or below the second lateral width W2. In some embodiments, when the first pitch P1 is 60% or less of the second pitch P2, a difference between the first lateral width W1 and the second lateral width W2 is 10% or less of W2. For example, the first lateral width W1 may be 10% or less above or below the second lateral width W2. In some embodiments, when the first pitch P1 and the second pitch P2 are within a range between 44 nm and 72 nm, a difference between the first lateral width W1 and the second lateral width W2 is 10% or less of W2. For example, the first lateral width W1 may be 10% or less above or below the second lateral width W2. In some embodiments, when the first pitch P1 and the second pitch P2 are within a range between 44 nm and 72 nm and the first pitch P1 is within a range between 80% and 90% of the second pitch P2, a difference between the first lateral width W1 and the second lateral width W2 is 2% or less of W2. For example, the first lateral width W1 may be 2% or less above or below the second lateral width W2. In some embodiments, when the first pitch P1 and the second pitch P2 are within a range between 44 nm and 72 nm and the first pitch P1 is within a range between 60% and 90% of the second pitch P2, a difference between the first lateral width W1 and the second lateral width W2 is 5% or less of W2. For example, the first lateral width W1 may be 5% or less above or below the second lateral width W2. In some embodiments, the difference between the first lateral width W1 and the second lateral width W2 is 0.5 nm or less, such as 0.25 nm or less, such as 0.1 nm or less. In some embodiments, the difference between the first lateral width W1 and the second lateral width W2 is 0.05 nm to 0.5 nm, such as 0.05 nm to 0.25 nm, such as 0.05 nm to 0.1 nm.

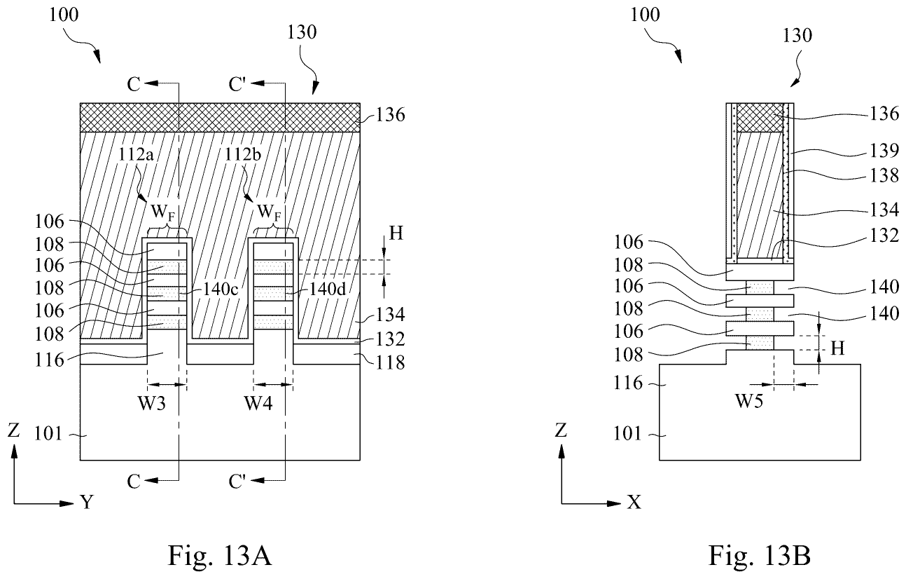

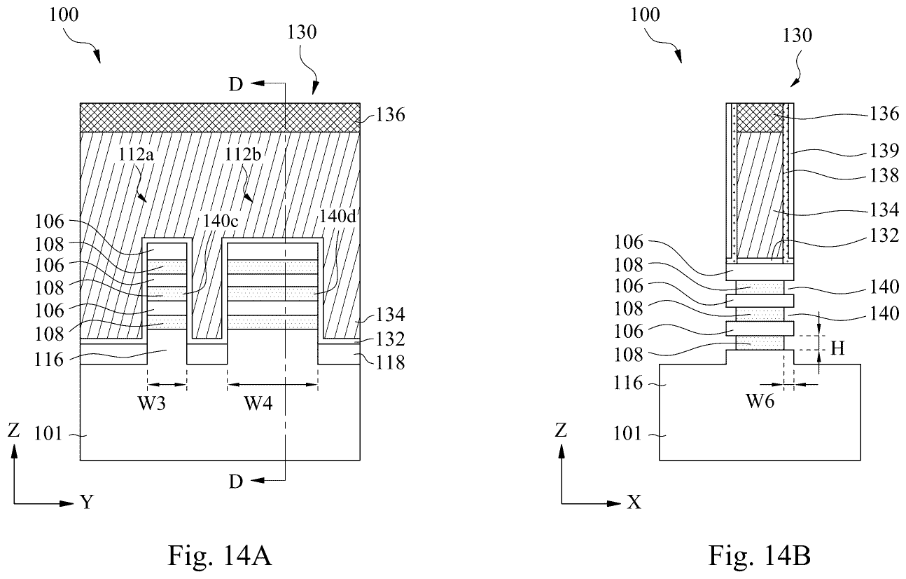

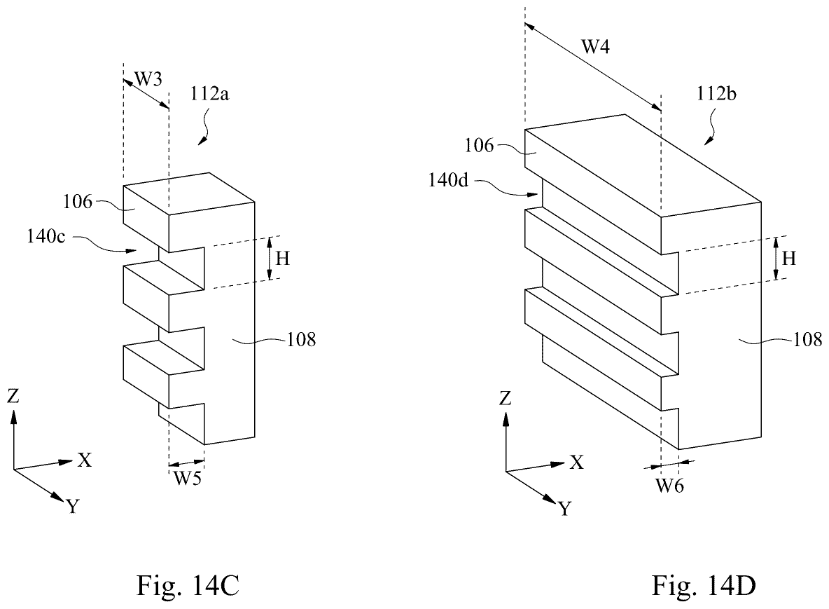

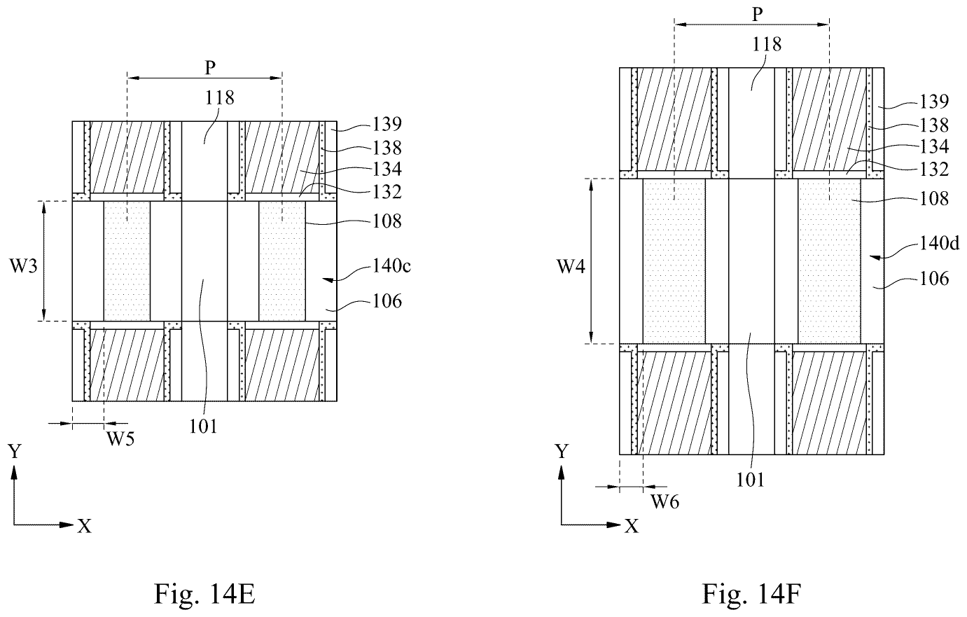

FIG. 13A is a cross-sectional side view taken along line B-B of FIG. 5, at the same stage of the process shown in FIG. 11. In this view, the fin structures 112 (which may be referred to as a “plurality of fin structures”) can be defined in terms of a fin width W_{F} in the Y direction. As shown in FIG. 13A, the fin structures 112 include a first fin structure 112a and a second fin structure 112b that extend lengthwise along a first axis (in the X direction). The fin widths W_{F} of the first fin structure 112a and the second fin structure 112b are defined along a second axis (in the Y direction) that is perpendicular to the first axis. In some embodiments, the fin widths W_{F} of the first fin structure 112a and the second fin structure 112b are the same (FIG. 13A). In some other embodiments, the fin widths W_{F} of the first fin structure 112a and the second fin structure 112b are different from each other (FIG. 14A), as described in more detail below.

As shown in FIG. 13A, first recesses 140c that result from removal of the edge portions of the second semiconductor layers 108 of the first fin structure 112a have a first width W3. Likewise, second recesses 140d that result from removal of the edge portions of the second semiconductor layers 108 of the second fin structure 112b have a second width W4. The first width W3 and the second width W4 correspond to fin widths W_{F} of the respective fin structures 112. Therefore, when the fin widths W_{F} of the first fin structure 112a and the second fin structure 112b are the same (FIG. 13A), the first width W3 is equal to the second width W4. The height H of the recesses 140 corresponds to a height of the respective edge portion of the second semiconductor layer 108 that is removed, as described above in connection with FIG. 10A. FIG. 13B is a cross-sectional side view taken along line C-C or line C′-C′ of FIG. 13A. The side view through either fin structure 112a or 112b is the same because the respective recesses 140c or 140d are equal in width in the X direction (lateral width W5). In other words, when the first width W3 is the same as the second width W4, the loading effect is zero, and the first recesses 140c and the second recesses 140d have equal lateral width W5.

FIGS. 14A and 14B depict alternative views of the semiconductor device structure 100 at the same stage of the process shown in FIGS. 13A and 13B. FIG. 14B is a cross-sectional side view taken along line D-D of FIG. 14A. In FIG. 14A, the first width W3 is less than the second width W4. In some embodiments, when the first width W3 is less than the second width W4, the lateral width W5 (first lateral width W5) (FIG. 13B) of the first recesses 140c is greater than a second lateral width W6 (FIG. 14B) of the second recesses 140d. In other words, the loading effect is greater for the first width W3 compared to the second width W4, at least because the first width W3 is less than the second width W4. Using a gas etchant that includes ClF₃, compared to other gases, in the dry etching process to form the recesses 140 can provide significant reductions in loading as described below. For example, with ClF₃, even when the first width W3 is less than the second width W4, a difference between the first lateral width W5 and the second lateral width W6 is below a threshold that is less than a characteristic threshold for etching differences with other gases. In other words, using a gas etchant that includes HF would result in higher loading, a higher threshold, and greater differences in etching based on fin width compared to ClF₃.

In some embodiments, when the first width W3 is 60% or less of the second width W4, a difference between the first lateral width W5 and the second lateral width W6 is 5% or less of W6. For example, the first lateral width W5 may be 5% or less above or below the second lateral width W6. In some embodiments, when the first width W3 is 30% or less of the second width W4, a difference between the first lateral width W5 and the second lateral width W6 is 10% or less of W6. For example, the first lateral width W5 may be 10% or less above or below the second lateral width W6. In some embodiments, when the first width W3 and the second width W4 are within a range between 19 nm and 60 nm, a difference between the first lateral width W5 and the second lateral width W6 is 10% or less of W6. For example, the first lateral width W5 may be 10% or less above or below the second lateral width W6. In some embodiments, when the first width W3 and the second width W4 are within a range between 19 nm and 60 nm and the first width W3 is within a range between 60% and 90% of the second width W4, a difference between the first lateral width W5 and the second lateral width W6 is 2% or less of W6. For example, the first lateral width W5 may be 2% or less above or below the second lateral width W6. In some embodiments, when the first width W3 and the second width W4 are within a range between 19 nm and 60 nm and the first width W3 is within a range between 30% and 90% of the second width W4, a difference between the first lateral width W5 and the second lateral width W6 is 5% or less of W6. For example, the first lateral width W5 may be 5% or less above or below the second lateral width W6. In some embodiments, the difference between the first lateral width W5 and the second lateral width W6 is 0.5 nm or less, such as 0.25 nm or less, such as 0.1 nm or less. In some embodiments, the difference between the first lateral width W5 and the second lateral width W6 is 0.05 nm to 0.5 nm, such as 0.05 nm to 0.25 nm, such as 0.05 nm to 0.1 nm.

FIGS. 14C and 14D are partial perspective views of the semiconductor device structures shown in the cross-sections of FIGS. 13B and 14B, respectively, in accordance with some embodiments. FIGS. 14E and 14F are partial top views taken along the X-Y plane of FIG. 5 and corresponding to the semiconductor device structures of FIGS. 13A and 14A, respectively, in accordance with some embodiments. As shown, the lateral width W5, W6 of the recesses 140c, 140d of the second semiconductor layers 108 depends on fin width W3, W4, subject to the loading effect. For example, greater differences in lateral width correspond to higher loading. The loading effect (e.g., based on fin width) can be reduced using processing techniques of the present disclosure, such as using a gas etchant that includes ClF₃, compared to other gases, in the dry etching process to form the recesses, as described in more detail below.

As described above, the lateral width can differ depending on where each second semiconductor layer 108 is located within the stack of semiconductor layers 104. In some embodiments, the differences in lateral width described in connection with different pitch (FIGS. 12A and 12B) and/or different fin width (FIGS. 14A and 14B) include comparisons in lateral width only between matching layers (e.g., top layer compared to top layer, middle layer compared to middle layer, and bottom layer compared to bottom layer) and not between different layers (e.g., top layer compared to middle layer or top layer compared to bottom layer). In some other embodiments, for example when the difference in lateral width between layers is nominal (such as 5% or less), the comparisons can apply between matching layers as well as between different layers.

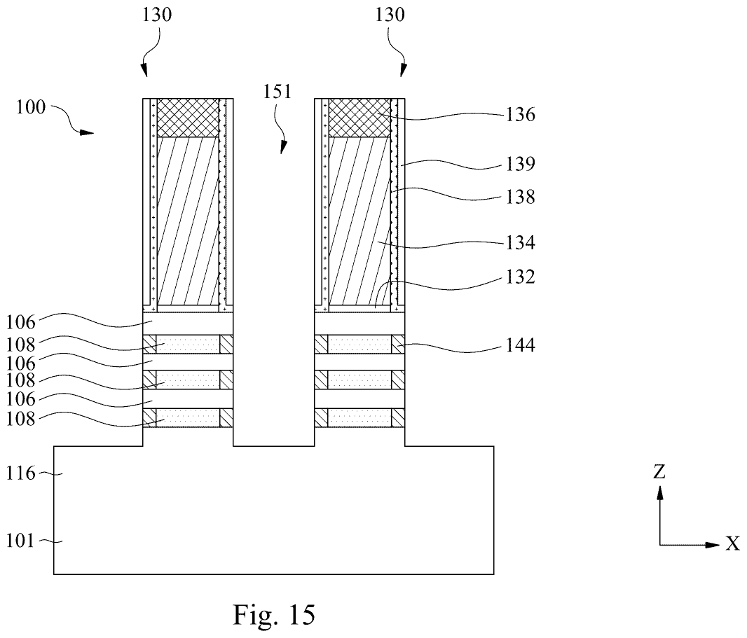

As shown in FIG. 15, which may follow immediately after FIG. 11, after removing edge portions of each second semiconductor layer 108, a dielectric layer is deposited in the cavities to form inner spacers 144. The inner spacers 144 may be made of a low-K dielectric material, such as SiON, SiCN, SiOC, SiOCN, or SiN. The inner spacers 144 may be formed by first forming a conformal dielectric layer using a conformal deposition process, such as ALD, followed by an anisotropic etching to remove portions of the conformal dielectric layer other than the inner spacers 144. The inner spacers 144 are protected by the first semiconductor layers 106 during the anisotropic etching process. The remaining second semiconductor layers 108 are capped between the inner spacers 144 along the X direction.

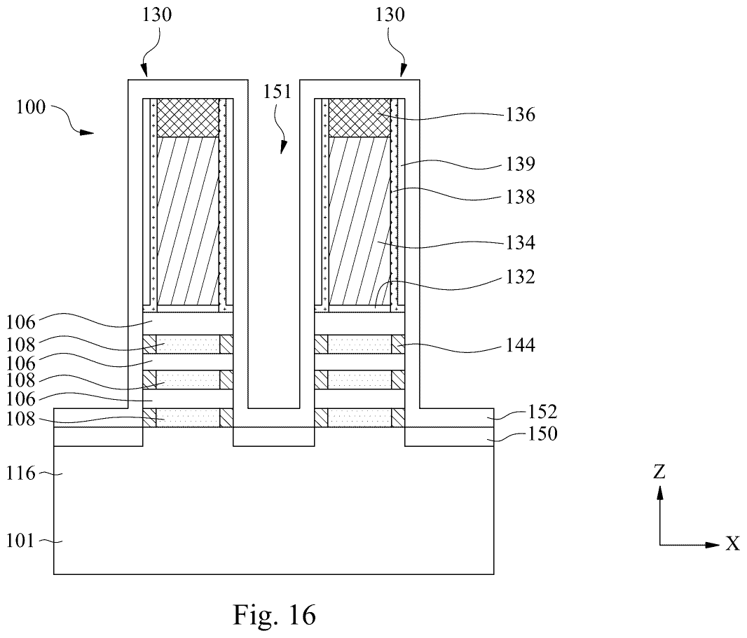

As shown in FIG. 16, a first semiconductor material 150 is formed on the exposed well portions 116 located at the bottoms of the trenches 151. In some embodiments, the first semiconductor material 150 includes undoped silicon or undoped SiGe. The first semiconductor material 150 may be first formed on semiconductor surfaces, such as on the exposed well portions 116 and on the first semiconductor layers 106, by epitaxy. The first semiconductor material 150 may be a buried epitaxial layer. A subsequent etch process is performed to remove the portions of the first semiconductor material 150 formed on the first semiconductor layers 106. The first semiconductor material 150 formed on the exposed well portions 116 may form a concave top surface as the result of the etch process. In some embodiments, the first semiconductor material 150 has a thickness ranging from about 5 nm to about 50 nm along the Z direction.

Next, as shown in FIG. 16, a dielectric layer 152 is formed on the semiconductor device structure 100. In some embodiments, formation of the dielectric layer 152 may define a deposition portion of a deposition-etching topography selective (DETS) process. In some embodiments, formation of the dielectric layer 152 can follow directly after an aluminum oxide removal process. The dielectric layer 152 is formed in the trenches 151 and over the sacrificial gate structures 130 and the first and second gate spacers 138, 139. The dielectric layer 152 may include any suitable dielectric material. In some embodiments, the dielectric layer 152 includes SiN. The dielectric layer 152 may be formed by any suitable process. In some embodiments, the dielectric layer 152 is formed by CVD. Portions of the dielectric layer 152 formed on vertical surfaces may have a first thickness, and portions of the dielectric layer 152 formed on horizontal surfaces may have a second thickness substantially greater than the first thickness. In some embodiments, the dielectric layer 152 includes a sidewall portion that is disposed on the vertical surfaces inside of each trench 151 and a bottom portion disposed on the first semiconductor material 150. For example, the sidewall portion of the dielectric layer 152 may be formed on the vertical surfaces of the inner spacers 144, the first semiconductor layers 106, and the first and second gate spacers 138, 139, as shown in FIG. 16. In some embodiments, the bottom portion of the dielectric layer 152 is substantially thicker than the sidewall portion of the dielectric layer 152. In some embodiments, the width of the trench 151 in the X direction ranges from about 22 nm to about 26 nm, and the thickness T1 may be greater than about 5 nm and less than about 10 nm. The bottom portion of the dielectric layer 152 may function as an isolation layer to prevent current leakage through the portion of the well portion 116 located below the bottommost second semiconductor layer 108.

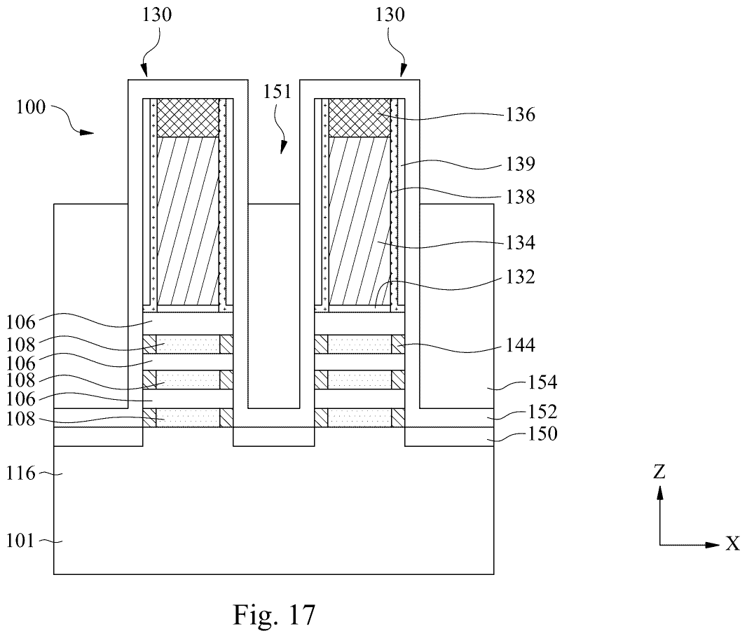

As shown in FIG. 17, a mask layer 154 is formed on the dielectric layer 152 and partially fills the trenches 151. The mask layer 154 may be a bottom antireflective coating (BARC) layer. The mask layer 154 may be formed by first forming a layer that completely fills the trenches 151 and over the sacrificial gate structures 130, and the layer is then recessed to form the mask layer 154. In some embodiments, the mask layer 154 may be recessed by a selective etch process that does not substantially affect the dielectric layer 152. The selective etch process may be a dry etch, a wet etch, or a combination thereof. In some embodiments, the selective etch process is a wet etch. In some embodiments, the mask layer 154 is in contact with a lower portion of the sidewall portion of the dielectric layer 152 in the trenches 151, and a upper portion of the sidewall portion of the dielectric layer 152 in the trenches 151 is exposed. In some embodiments, the top surface of the mask layer 154 in the trench 151 is located at a level between the top surface and the bottom surface of the sacrificial gate electrode layer 134, as shown in FIG. 17. In some embodiments, the top surface of the mask layer 154 in the trench 151 may be located at a level below the bottom surface of the sacrificial gate electrode layer 134, such as at a level below the topmost first semiconductor layer 106, for example between the top surface and the bottom surface of the second first semiconductor layer 106 from the bottom. The sidewall portion of the dielectric layer 152 is to be removed in subsequent processes, and the bottom portion of the dielectric layer 152 is to remain. Thus, the mask layer 154 protects the bottom portion of the dielectric layer 152 during the subsequent removal of the upper portion of the sidewall portion and the subsequent recessing of the lower portion of the sidewall portion of the dielectric layer 152.

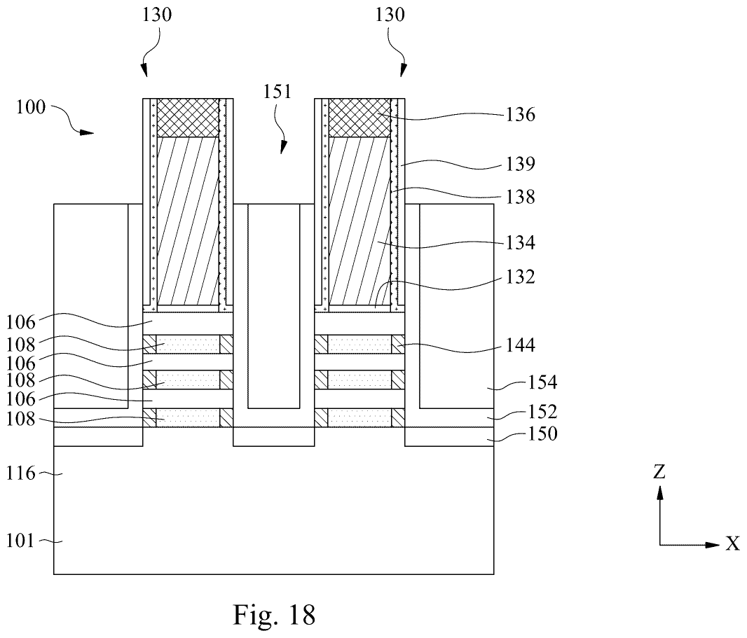

As shown in FIG. 18, the exposed upper portion of the sidewall portion of the dielectric layer 152 in each trench 151 and portions of the dielectric layer 152 located over the sacrificial gate structures 130 and the first and second gate spacers 138, 139 are removed. The portions of the dielectric layer 152 may be removed by a selective etch process, such as a dry etch, a wet etch, or a combination thereof. The selective etch process removes the exposed upper portion of the sidewall portion of the dielectric layer 152 but does not substantially affect the mask layer 154, the first and second gate spacers 138, 139, and the mask layer 136. The remaining lower portion of the sidewall portion of the dielectric layer 152 located in the trench 151 may include a top surface substantially coplanar with a top surface of the mask layer 154, as shown in FIG. 18.

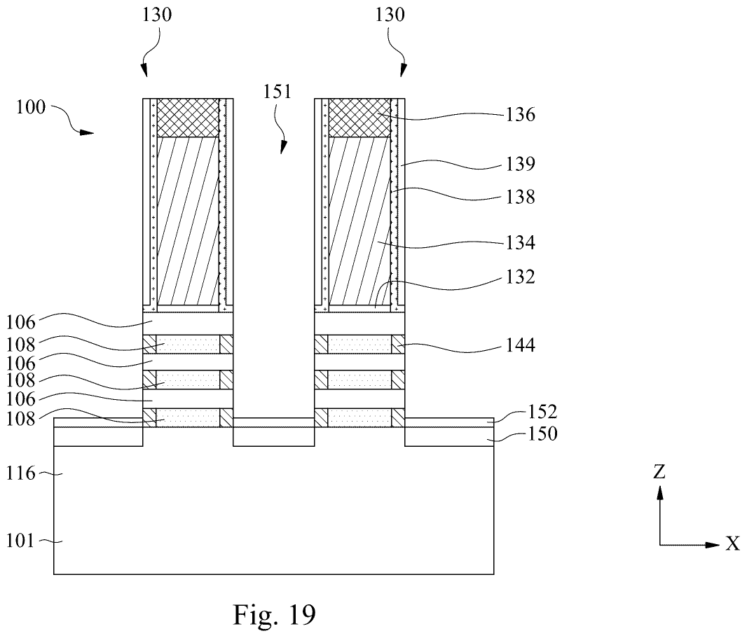

As shown in FIG. 19, the mask layer 154 and the lower portion of the sidewall portion of the dielectric layer 152 are removed. The mask layer 154 and the sidewall portion of the dielectric layer 152 may be removed by any suitable process. In some embodiments, the lower portion of the sidewall portion of the dielectric layer 152 is first recessed by a selective etch process, and the recessed dielectric layer 152 has the top surface located substantially below the top surface of the mask layer 154. The selective etch process recesses the dielectric layer 152 but does not substantially affect the mask layer 136, the first and second gate spacers 138, 139, and the mask layer 154. In some embodiments, the top surface of the recessed dielectric layer 152 is located at a level between the top surface and the bottom surface of the bottommost first semiconductor layer 106. In some embodiments, the selective etch process to recess the lower portion of the sidewall portion of the dielectric layer 152 and the selective etch process to remove the exposed upper portion of the sidewall portion of the dielectric layer 152 are the same selective etch process. In other words, a single selective etch process may be performed to remove the exposed upper portion of the sidewall portion of the dielectric layer 152 and to recess the lower portion of the sidewall portion of the dielectric layer 152.

Next, the mask layer 154 is removed. The mask layer 154 may be removed by a selective process. In some embodiments, the mask layer 154 is removed using a stripping process, such as using a solvent or an oxygen plasma. The selective process to remove the mask layer 154 does not substantially affect the mask layer 136, the first and second gate spacers 138, 139, the first semiconductor layers 106, the inner spacers 144, and the dielectric layer 152. After the removal of the mask layer 154, the dielectric layer 152 includes the sidewall portion, which is the recessed lower portion of the sidewall portion, and the bottom portion. As described above, the top surface of the sidewall portion of the dielectric layer 152 may be located at a level between the top surface and the bottom surface of the bottommost first semiconductor layer 106.

Next, an etch process is performed to remove the sidewall portion of the dielectric layer 152, while the bottom portion of the dielectric layer 152 remains. As described above, the sidewall portion of the dielectric layer 152 has the first thickness, which is substantially less than the second thickness of the bottom portion of the dielectric layer 152. As a result, the etch process completely removes the sidewall portion of the dielectric layer 152, while the second thickness of the bottom portion of the dielectric layer 152 is reduced. In some embodiments, the second thickness of the bottom portion of the dielectric layer 152 after the removal of the sidewall portion of the dielectric layer 152 ranges from about 5 nm to about 8 nm. The etch process may be any suitable etch process, such as a dry etch process, a wet etch process, or a combination thereof. After the etch process to remove the sidewall portion of the dielectric layer 152, the dielectric layer 152 (the remaining bottom portion) is disposed on the first semiconductor material 150, as shown in FIG. 19.

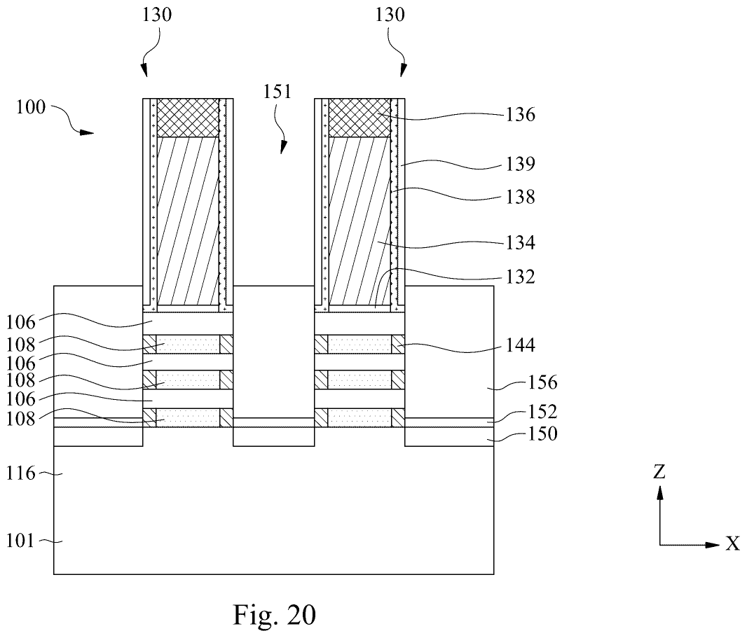

As shown in FIG. 20, a second semiconductor material 156 is formed in the trenches 151, and the second semiconductor material 156 may be epitaxially grown from the first semiconductor layers 106. The second semiconductor material 156 may grow both vertically and horizontally to form facets, which may correspond to crystalline planes of the material used for the first semiconductor layer 106. The second semiconductor material 156 may be the source/drain (S/D) region. In this disclosure, a source region and a drain region are interchangeably used, and the structures thereof are substantially the same. Furthermore, source/drain region(s) may refer to a source or a drain, individually or collectively dependent upon the context. The second semiconductor material 156 may be made of one or more layers of Si, SiP, SiC and SiCP for n-channel FETs or Si, SiGe, Ge for p-channel FETs. For p-channel FETs, p-type dopants, such as boron (B), may also be included in the second semiconductor material 156. The second semiconductor material 156 may be formed by an epitaxial growth method using CVD, ALD or MBE.

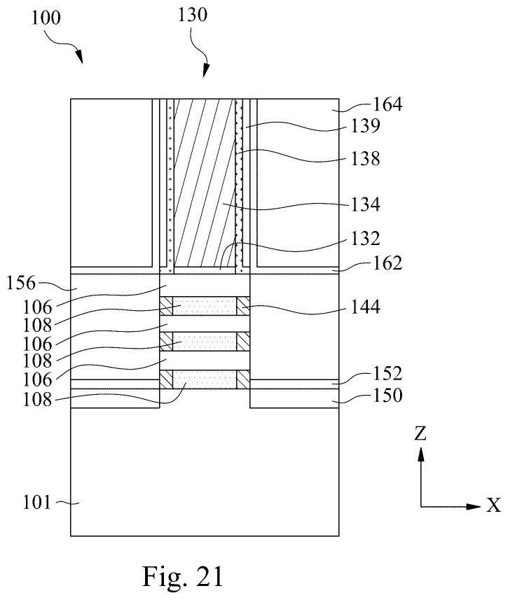

FIGS. 21-23 are cross-sectional side views of various stages of manufacturing the semiconductor device structure 100 taken along line A-A of FIG. 5. The semiconductor device structure 100 can include any number of sacrificial gate structures 130, as described above. However, in these figures only one sacrificial gate structure 130 is shown (similar to FIGS. 6-10). As shown in FIG. 21, a contact etch stop layer (CESL) 162 is conformally formed on the exposed surfaces of the semiconductor device structure 100. The CESL 162 covers the second gate spacer 139, the isolation regions 120, and the second semiconductor material 156. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. In some embodiments, the CESL 162 is a single layer, as shown in FIG. 21. In some embodiments, the CESL 162 includes two or more layers. Next, an interlayer dielectric (ILD) layer 164 is formed on the CESL 162. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164. After the ILD layer 164 is formed, a planarization operation, such as CMP, is performed on the semiconductor device structure 100 until the sacrificial gate electrode layer 134 is exposed, as shown in FIG. 21.

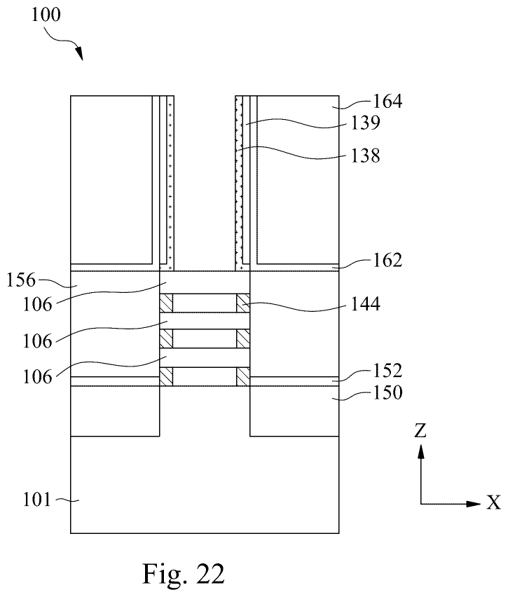

As shown in FIG. 22, the sacrificial gate structure 130 and the second semiconductor layers 108 are removed. The removal of the sacrificial gate structure 130 and the semiconductor layers 108 forms an opening between the first gate spacers 138 and between the first semiconductor layers 106. The ILD layer 164 protects the second semiconductor material 156 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the first gate spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the first gate spacers 138, and the inner spacers 144. In one embodiment, the second semiconductor layers 108 can be removed using a wet etchant such as, but not limited to, hydrofluoric (HF), nitric acid (HNO₃), hydrochloric acid (HCl), or phosphoric acid (H₃PO₄).

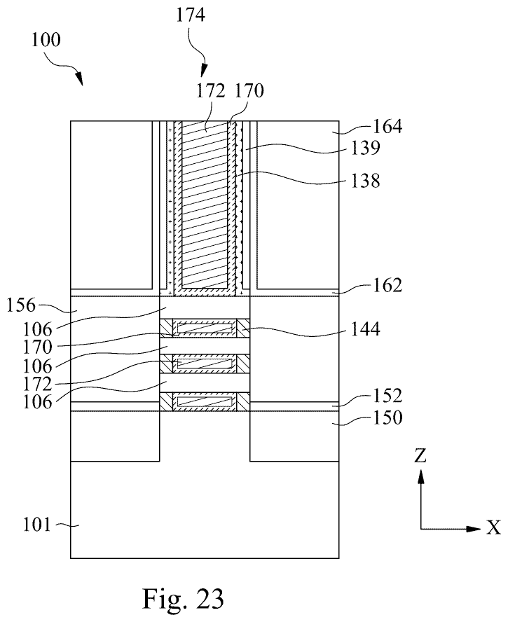

As shown in FIG. 23, after the formation of the nanostructure channels (i.e., the exposed portions of the first semiconductor layers 106), a gate dielectric layer 170 is formed to surround the exposed portions of the first semiconductor layers 106, the inner spacers 144, the sidewall spacers 138, and the isolation regions 118. A gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

It is understood that the semiconductor device structure 100 may undergo further processes to form conductive contacts in the ILD layer 164 to be electrically connected to the second semiconductor material 156 and to form conductive contacts to be electrically connected to the gate electrode layer 172. An interconnect structure may be formed over the semiconductor device structure 100 to provide electrical paths to the devices formed on the substrate 101.

Embodiments of the present disclosure provide a method of forming a semiconductor device structure with a fin structure that includes a first plurality of semiconductor layers made of Si and a second plurality of semiconductor layers made of SiGe. The method includes removing edge portions of the second plurality of semiconductor layers in a lateral direction to form recesses. To remove the edge portions, in accordance with embodiments disclosed herein, a selective dry etching process is performed using a gas etchant that includes ClF₃. For semiconductor devices with a gate pitch or fin width that varies across structures on the same substrate, there can be a loading effect that causes the etching amount of the recesses to vary based on respective differences in gate pitch or fin width. This can present a particular problem for certain ones of the non-uniform recesses that are subsequently filled with an insulating material that has an undesirable thickness. For example, when the loading effect results in a recess being etched by too small an amount, the dielectric spacer that is formed in place of the recess may be too thin such that current leakage can occur across the dielectric layer. However, performing the selective dry etching process with ClF₃ is able to overcome this problem. Using a gas etchant that includes ClF₃, compared to other gases, in the dry etching process to form the recesses can provide significant reductions in loading and improved recess uniformity (dielectric spacer uniformity) as described herein. For example, with ClF₃, even when the gate pitch or fin width varies, the difference in etching (and recess width) remains below a threshold that is less than a characteristic threshold for etching differences with other gases. In other words, using a gas etchant that includes HF would result in higher loading, a higher threshold, and greater differences in etching based on gate pitch or fin width compared to ClF₃. In addition to, or as a result of, the reduction in loading, using the gas etchant that includes ClF₃, as described herein, can provide improved control of MG CD profile, improved device performance, and/or improved yield.

In some embodiments, a method includes forming one or more fin structures on a substrate, wherein the one or more fin structures include a first plurality of semiconductor layers made of a first semiconductor material and a second plurality of semiconductor layers made of a second semiconductor material; forming a plurality of sacrificial gate stacks over the one or more fin structures, wherein a first distance between a first pair of adjacent sacrificial gate stacks of the plurality of sacrificial gate stacks defines a first pitch, and wherein a second distance between a second pair of adjacent sacrificial gate stacks of the plurality of sacrificial gate stacks defines a second pitch that is different from the first pitch; removing portions of the one or more fin structures adjacent to the plurality of sacrificial gate stacks to expose portions of the substrate; removing edge portions of the second plurality of semiconductor layers in a lateral direction to form recesses, wherein removing the edge portions includes performing a selective dry etching process using a gas etchant that includes ClF₃; forming inner spacers in the recesses; forming source/drain (S/D) regions adjacent to the plurality of sacrificial gate stacks; removing the plurality of sacrificial gate stacks and the second plurality of semiconductor layers; and forming one or more gate structures in place of the plurality of sacrificial gate stacks and the second plurality of semiconductor layers.

In some embodiments, a method includes forming, on a substrate, a plurality of fin structures including a first plurality of semiconductor layers made of a first semiconductor material and a second plurality of semiconductor layers made of a second semiconductor material, wherein first and second fin structures of the plurality of fin structures extend lengthwise along a first axis, and wherein a first width of the first fin structure defined along a second axis perpendicular to the first axis is different from a second width of the second fin structure defined along the second axis; forming a sacrificial gate stack over the first and second fin structures, wherein the sacrificial gate stack extends lengthwise along the second axis; removing portions of the first and second fin structures adjacent to the sacrificial gate stack to expose portions of the substrate; removing edge portions of the second plurality of semiconductor layers in a lateral direction to form recesses, wherein removing the edge portions includes performing a selective dry etching process using a gas etchant that includes ClF₃; forming inner spacers in the recesses; forming source/drain (S/D) regions adjacent to the sacrificial gate stack; removing the sacrificial gate stack and the second plurality of semiconductor layers; and forming a gate structure in place of the sacrificial gate stack and the second plurality of semiconductor layers.

In some embodiments, a method includes forming a fin structure on a substrate, wherein the fin structure includes a first plurality of semiconductor layers made of Si and a second plurality of semiconductor layers made of SiGe; forming a sacrificial gate stack over the fin structure; removing portions of the fin structure adjacent to the sacrificial gate stack to expose a portion of the substrate; removing edge portions of the second plurality of semiconductor layers in a lateral direction to form recesses, wherein removing the edge portions includes performing a selective dry etching process using a gas etchant that includes ClF₃; forming inner spacers in the recesses; forming a source/drain (S/D) region adjacent to the sacrificial gate stack; removing the sacrificial gate stack and the second plurality of semiconductor layers; and forming a gate structure in place of the sacrificial gate stack and the second plurality of semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming one or more fin structures on a substrate, wherein the one or more fin structures include a first plurality of semiconductor layers made of a first semiconductor material and a second plurality of semiconductor layers made of a second semiconductor material;
forming a plurality of sacrificial gate stacks over the one or more fin structures, wherein a first distance between a first pair of adjacent sacrificial gate stacks of the plurality of sacrificial gate stacks defines a first pitch, and wherein a second distance between a second pair of adjacent sacrificial gate stacks of the plurality of sacrificial gate stacks defines a second pitch that is different from the first pitch;
removing portions of the one or more fin structures adjacent to the plurality of sacrificial gate stacks to expose portions of the substrate;
removing edge portions of the second plurality of semiconductor layers in a lateral direction to form recesses, wherein removing the edge portions includes performing a selective dry etching process using a gas etchant that includes ClF₃;
forming inner spacers in the recesses;
forming source/drain (S/D) regions adjacent to the plurality of sacrificial gate stacks;
removing the plurality of sacrificial gate stacks and the second plurality of semiconductor layers; and
forming one or more gate structures in place of the plurality of sacrificial gate stacks and the second plurality of semiconductor layers.

2. The method of claim 1, wherein the first pitch is less than the second pitch, wherein removing the edge portions of the second plurality of semiconductor layers includes forming first recesses associated with the first pair of adjacent sacrificial gate stacks and forming second recesses associated with the second pair of adjacent sacrificial gate stacks, and wherein a difference between a first lateral width of the first recesses and a second lateral width of the second recesses is below a threshold.

3. The method of claim 2, wherein when the first pitch is 80% or less of the second pitch, the difference between the first lateral width and the second lateral width is 5% or less of the second lateral width.

4. The method of claim 2, wherein when the first pitch is 60% or less of the second pitch, the difference between the first lateral width and the second lateral width is 10% or less of the second lateral width.

5. The method of claim 2, wherein the first pitch is within a range between 44 nm and 72 nm, wherein the second pitch is within a range between 44 nm and 72 nm, and wherein the difference between the first lateral width and the second lateral width is 10% or less of the second lateral width.

6. The method of claim 2, wherein the first pitch is within a range between 44 nm and 72 nm, wherein the second pitch is within a range between 44 nm and 72 nm, wherein the first pitch is within a range between 80% and 90% of the second pitch, and wherein the difference between the first lateral width and the second lateral width is 2% or less of the second lateral width.

7. The method of claim 2, wherein the first pitch is within a range between 44 nm and 72 nm, wherein the second pitch is within a range between 44 nm and 72 nm, wherein the first pitch is within a range between 60% and 90% of the second pitch, and wherein the difference between the first lateral width and the second lateral width is 5% or less of the second lateral width.

8. A method, comprising:
forming, on a substrate, a plurality of fin structures including a first plurality of semiconductor layers made of a first semiconductor material and a second plurality of semiconductor layers made of a second semiconductor material, wherein first and second fin structures of the plurality of fin structures extend lengthwise along a first axis, and wherein a first width of the first fin structure defined along a second axis perpendicular to the first axis is different from a second width of the second fin structure defined along the second axis;
forming a sacrificial gate stack over the first and second fin structures, wherein the sacrificial gate stack extends lengthwise along the second axis;
removing portions of the first and second fin structures adjacent to the sacrificial gate stack to expose portions of the substrate;
removing edge portions of the second plurality of semiconductor layers in a lateral direction to form recesses, wherein removing the edge portions includes performing a selective dry etching process using a gas etchant that includes ClF₃;
forming inner spacers in the recesses;
forming source/drain (S/D) regions adjacent to the sacrificial gate stack;
removing the sacrificial gate stack and the second plurality of semiconductor layers; and
forming a gate structure in place of the sacrificial gate stack and the second plurality of semiconductor layers.

9. The method of claim 8, wherein the first width is less than the second width, wherein removing the edge portions of the second plurality of semiconductor layers includes forming first recesses associated with the first fin structure and forming second recesses associated with the second fin structure, and wherein a difference between a first lateral width of the first recesses and a second lateral width of the second recesses is below a threshold.

10. The method of claim 9, wherein when the first width is 60% or less of the second width, the difference between the first lateral width and the second lateral width is 5% or less of the second lateral width.

11. The method of claim 9, wherein when the first width is 30% or less of the second width, the difference between the first lateral width and the second lateral width is 10% or less of the second lateral width.

12. The method of claim 9, wherein the first width is within a range between 19 nm and 60 nm, wherein the second width is within a range between 19 nm and 60 nm, and wherein the difference between the first lateral width and the second lateral width is 10% or less of the second lateral width.

13. The method of claim 9, wherein the first width is within a range between 19 nm and 60 nm, wherein the second width is within a range between 19 nm and 60 nm, wherein the first width is within a range between 60% and 90% of the second width, and wherein the difference between the first lateral width and the second lateral width is 2% or less of the second lateral width.

14. The method of claim 9, wherein the first width is within a range between 19 nm and 60 nm, wherein the second width is within a range between 19 nm and 60 nm, wherein the first width is within a range between 30% and 90% of the second width, and wherein the difference between the first lateral width and the second lateral width is 5% or less of the second lateral width.

15. A method, comprising:
forming a fin structure on a substrate, wherein the fin structure includes a first plurality of semiconductor layers made of Si and a second plurality of semiconductor layers made of SiGe;
forming a sacrificial gate stack over the fin structure;
removing portions of the fin structure adjacent to the sacrificial gate stack to expose a portion of the substrate;
removing edge portions of the second plurality of semiconductor layers in a lateral direction to form recesses, wherein removing the edge portions includes performing a selective dry etching process using a gas etchant that includes ClF₃;
forming inner spacers in the recesses;
forming a source/drain (S/D) region adjacent to the sacrificial gate stack;
removing the sacrificial gate stack and the second plurality of semiconductor layers; and
forming a gate structure in place of the sacrificial gate stack and the second plurality of semiconductor layers.

16. The method of claim 15, wherein the gas etchant further includes F₂.

17. The method of claim 16, wherein the gas etchant does not include HF.

18. The method of claim 16, wherein a flow rate of ClF₃ is within a range between 50 standard cubic centimeters per minute (SCCM) and 100 SCCM.

19. The method of claim 16, wherein a volume fraction of ClF₃ in the gas etchant is within a range between 50% and 90%.

20. The method of claim 16, wherein a temperature of the gas etchant is within a range between 25° C. and 35° C.
